(19) United States
(12) Patent Application Publication
(10) Pub. No.: US 2009/0026525 A1
(43) Pub. Date: Jan. 29, 2009

(54) MEMORY AND METHOD FOR FABRICATING THE SAME

(75) Inventors: Pin-Yao Wang, Hsinchu City (TW); Liang-Chuan Lai, Hsinchu County (TW); Michael Ying-li Liu, Chiayi City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 11/872,723

(22) Filed: Oct. 16, 2007

(30) Foreign Application Priority Data
Jul. 23, 2007 (TW) 96126781

(51) Int. Cl. H01L 29/788; H01L 21/44

(52) U.S. Cl. 257/316; 438/669; 257/E29.3; 257/E21.476

(57) ABSTRACT

A method for fabricating a memory is provided. A tunneling dielectric layer, a first conductive layer, and a mask layer are formed on a substrate. The mask layer, the first conductive layer, the tunneling dielectric layer, and the substrate are patterned to form trenches in the substrate. A passivation layer and isolation structures are formed in sequence to fill the trenches, and the etching rate of the isolation structures is greater than that of the passivation layer. After the mask layer is removed, a second conductive layer is formed on the first conductive layer. Portions of the isolation structures are removed to expose the sidewalls of the first and the second conductive layers. Further, a third conductive layer is formed on the exposed sidewalls of the first and the second conductive layers. An inter-gate dielectric layer and a control gate are formed on the substrate.

### BACKGROUND OF THE INVENTION

1. Field of the Invention

The present invention relates to a semiconductor device and a method for fabricating the same. More particularly, the present invention relates to a memory and a method for fabricating the same.

2. Description of Related Art

Non-volatile memory device is a kind of memory characterized by the advantages that it allows multiple data storing, reading or erasing operations. The data stored in the non-volatile memory will be retained even if the power applied to the device is cut off. The non-volatile memory has become a widely adopted memory device in personal computers and electronic equipments.

A typical memory device is generally designed into a stacked gate structure formed by a floating gate and a control gate. The floating gate is disposed between the control gate and a substrate, and is floating instead of being connected to any circuit. The control gate is connected to a word line. Besides, the floating gate and the control gate are isolated by an inter-gate dielectric layer, and the floating gate and the substrate are isolated by a tunneling dielectric layer.

Generally speaking, a gate-coupling ratio (GCR) is one of the key parameters for determining an operating performance of a memory device. The larger the GCR between the floating gate and the control gate is, the lower the required working voltage will be, and accordingly, the operating speed and efficiency of the memory device will rise. The GCR refers to a ratio of the capacitance between the floating gate and the control gate and the total capacitance of the memory, so the GCR may be enhanced by increasing the equivalent capacitance contact area between the floating gate and the control gate.

However, under the continuous trend in pursuit of high integrity of the IC design, the area occupied by each memory cell of the memory device must be reduced, and the line width of the device is reduced accordingly. As such, the GCR between the floating gate and the control gate is lowered, and the operating voltage required by the memory device is forced to rise. The above situation is rather disadvantageous for applying the memory device to a portable electronic product required of low power consumption.

Therefore, it becomes an important subject to provide a memory device of high GCR on a limited chip area by a simple fabrication method.

### SUMMARY OF THE INVENTION

The present invention provides a method for fabricating a memory, so as to prevent the control gate from directly contacting the substrate, and to increase the capacitance contact area between the floating gate and the control gate, thus enhancing the GCR between the floating gate and the control gate.

The present invention provides a memory, in which the capacitance contact area between the floating gate and the control gate is large, thus achieving a high GCR, so as to enhance the use performance of the device.

The present invention provides a method for fabricating a memory. A tunneling dielectric layer, a first conductive layer, and a mask layer are formed in sequence on a substrate. The mask layer, the first conductive layer, the tunneling dielectric layer, and the substrate are then patterned to form a plurality of trenches in the substrate. A passivation layer is formed on the surface of the trenches. A plurality of isolation structures is formed to fill the trenches, and an etching rate of the isolation structures is greater than that of the passivation layer. The mask layer is removed to expose the first conductive layer. A second conductive layer is formed on the first conductive layer. Portions of the isolation structures are removed for lowering the surface of the isolation structures than that of the substrate and exposing sidewalls of the first and the second conductive layers. Further, a third conductive layer is formed on the exposed sidewalls of the first and the second conductive layers. The third conductive layer, the second conductive layer, and the first conductive layer are patterned to form a plurality of floating gates. Afterwards, an inter-gate dielectric layer is formed on the substrate. Then, a control gate is formed on the substrate.

In an embodiment of the present invention, the passivation layer is, for example, a composite layer.

In an embodiment of the present invention, the process for forming the composite layer includes, for example, first forming a liner on the surface of the trenches, and then forming an insulating layer on the surface of the trenches.

In an embodiment of the present invention, the material of the insulating layer is, for example, silicon oxide formed by high-density plasma CVD (HDP-CVD).

In an embodiment of the present invention, a material of the insulating layer is, for example, silicon nitride.

In an embodiment of the present invention, a process for forming the liner is, for example, thermal oxidation.

In an embodiment of the present invention, a process for removing portions of the isolation structures is, for example, wet etching.

In an embodiment of the present invention, a process for forming the isolation structures is, for example, first forming an insulating material layer on the substrate to fill the trenches, and then removing the portion of the insulating material layer remaining outside the trenches.

In an embodiment of the present invention, a material of the insulating material layer is, for example, spin-on dielectric (SOD).

In an embodiment of the present invention, a process for forming the third conductive layer is, for example, first forming a conductive material layer covered on the second conductive layer and the isolation structures, and then removing portions of the conductive material layer to expose the surface of the isolation structures.

In an embodiment of the present invention, a process for removing portions of the conductive material layer is, for example, etch-back.

The present invention further provides a memory, which includes a plurality of trench isolation structures, a plurality of passivation layers, a gate structure, and a source/drain region is provided. The trench isolation structures are disposed in a substrate, and the surface of the trench isolation structures is lower than that of the substrate. The passivation layers are disposed between the trench isolation structures and the substrate, and an etching rate of the trench isolation structures is greater than that of the passivation layers. The gate structure includes a floating gate, a tunneling dielectric layer, a control gate, and an inter-gate dielectric layer. The floating gate is disposed on the substrate between two adjacent trench isolation structures, and is covered on a portion of the surface of the trench isolation structures. The tunneling dielectric layer is disposed between the floating gate and the substrate. The control gate is disposed on the substrate, and is covered on the floating gate and the trench isolation structures. The inter-gate dielectric layer is disposed between the control gate and the floating gate, and between the control gate and the substrate. The source/drain region is disposed in the substrate on both sides of the gate structure.

In an embodiment of the present invention, the passivation layer is, for example, a composite layer.

In an embodiment of the present invention, the composite layer includes a silicon oxide layer.

In an embodiment of the present invention, the composite layer includes a silicon nitride layer.

In an embodiment of the present invention, a material of the trench isolation structures is, for example, SOD.

In an embodiment of the present invention, a material of the floating gate is, for example, doped polysilicon.

In an embodiment of the present invention, a material of the control gate is, for example, doped polysilicon.

In an embodiment of the present invention, a material of the tunneling dielectric layer is, for example, silicon oxide.

In an embodiment of the present invention, a material of the inter-gate dielectric layer is, for example, silicon oxide/silicon nitride/silicon oxide (ONO).

In the method for fabricating a memory of the present invention, a passivation layer is formed between the isolation structures and the substrate, so portions of the isolation structures may be removed by wet etching. A third conductive layer serving as a portion of the floating gate is formed on the sidewalls of the first and the second conductive layers, thus increasing the contact area between the floating gate and the control gate, so as to enhance the GCR. Moreover, the method provided by the present invention increases the contact area between the floating gate and the control gate through a simple process, and meanwhile prevents the over etch by the use of the passivation layer, thus reducing the fabrication cost.

In another aspect, the memory of the present invention has a portion of the floating gate disposed on the isolation structures, the capacitance contact area between the control gate and the floating gate is increased to enhance the GCR of the memory, thereby lowering the operating voltage of the device and improving the device performance.

In order to make the aforementioned features and advantages of the present invention comprehensible, embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1E are schematic cross-sectional views of processes of fabricating a memory according to an embodiment of the present invention.

### DESCRIPTION OF EMBODIMENTS

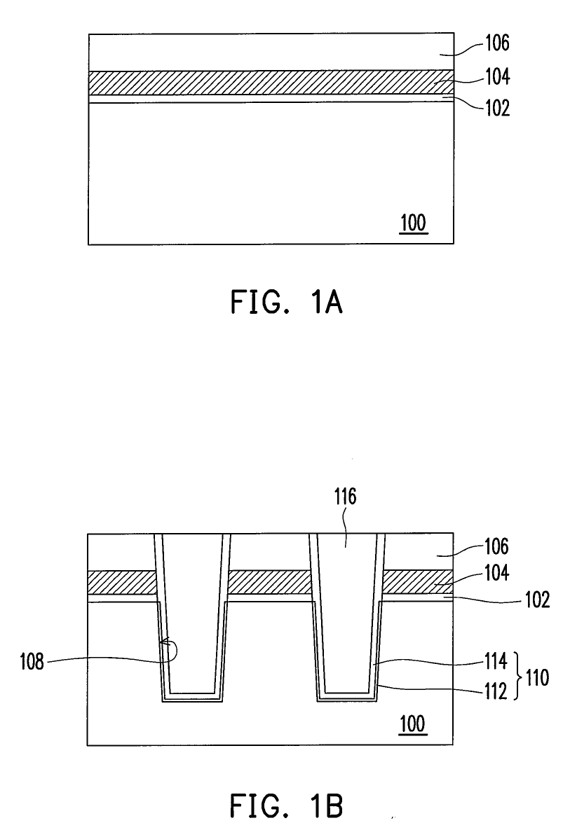

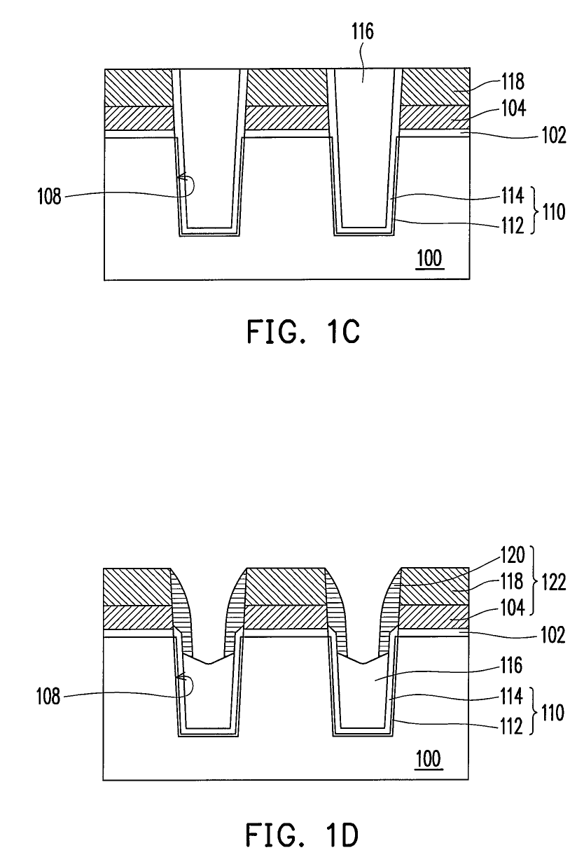

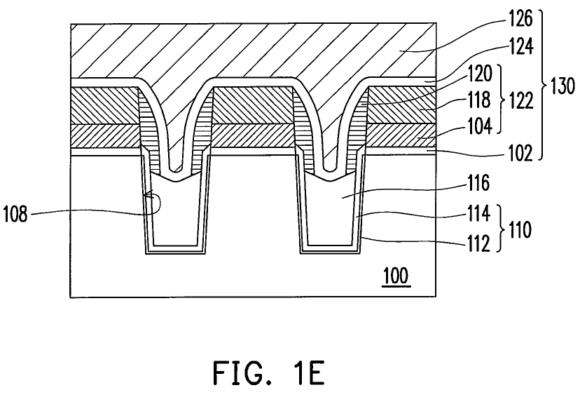

FIGS. 1A to 1E are schematic cross-sectional views of processes of fabricating a memory according to an embodiment of the present invention.

Referring to FIG. 1A, a substrate 100 is provided. The substrate 100 is, for example, a silicon substrate or other suitable semiconductor substrates. Next, a tunneling dielectric layer 102 is formed on the substrate 100. The material of the tunneling dielectric layer 102 is, for example, silicon oxide. The tunneling dielectric layer 102 is formed by performing thermal oxidation or CVD, for example. Then, a conductive layer 104 is formed on the tunneling dielectric layer 102. The material of the conductive layer 104 is, for example, doped polysilicon. The conductive layer 104 is formed by performing CVD, for example. After that, a mask layer 106 is formed on the conductive layer 104. The material of the mask layer 106 is, for example, silicon nitride or other suitable dielectric materials. The mask layer 106 is formed by performing CVD, for example.

Referring to FIG. 1B, a patterned photoresist layer (not shown) is formed on the mask layer 106, and exposes a portion of the mask layer 106. The exposed portion of the mask layer 106 is removed by using the patterned photoresist layer as the mask. Then, the patterned photoresist layer is removed. Afterwards, portions of the conductive layer 104, the tunneling dielectric layer 102, and the substrate 100 are removed with the remaining mask layer 106 as the mask, so as to form trenches 108 in the substrate 100. The method for removing portions of the conductive layer 104, the tunneling dielectric layer 102, and the substrate 100 is, for example, dry etching. Next, a passivation layer 110 is formed on the surface of the trenches 108. The passivation layer 110 is, for example, a composite layer consisting of several dielectric material layers. That is to say, as shown in FIG. 1B, the passivation layer 110 is composed of a liner 112 and an insulating layer 114. The material of the liner 112 is, for example, silicon oxide. The material of the insulating layer 114 is, for example, silicon oxide or silicon nitride. In this embodiment, the material of both the liner 112 and the insulating layer 114 is silicon oxide. The method for forming the passivation layer 110 includes, for example, first forming the liner 112 on the surface of the trenches 108 through thermal oxidation, and then forming the insulating layer 114 on the surface of the trenches 108 through HDP-CVD.

Then, referring to FIG. 1B, an insulating material layer (not shown) is formed on the substrate 100 to fill the trenches 108. Then, a portion of the insulating material layer is removed to form a plurality of isolation structures 116 in the trenches 108. The method for removing a portion of the insulating material layer is, for example, chemical-mechanical polishing (CMP) or etch-back. In the step of removing a portion of the insulating material layer, for example, the mask layer 106 severs as a polish stop layer or an etch stop layer. Moreover, the material of the above insulating material layer is, for example, SOD. In this embodiment, the insulating material layer is a silicon oxide layer formed by spin-on coating. The insulating material layer is, for example, formed by evaporation to remove solvent through two-stage heating.

Referring to FIG. 1C, the mask layer 106 is removed, so as to expose the conductive layer 104. The method for removing the mask layer 106 is, for example, wet etching. Afterwards, a conductive layer 118 is formed on the substrate 100, and is covered on the conductive layer 104 and the isolation structures 116. The material of the conductive layer 118 is, for example, doped polysilicon. The conductive layer 118 is formed by performing CVD, for example. Next, a portion of the conductive layer 118 is removed to expose the surface of the isolation structures 116. The method for removing a portion of the conductive layer 118 is, for example, CMP, and the isolation structures 116, for example, function as polish stop layers. The remaining conductive layer 118 is covered on the conductive layer 104.

Referring to FIG. 1D, portions of the isolation structures 116 are removed for lowering the surface of the isolation structures 116 than that of the substrate 100 and exposing portions of the sidewalls of the conductive layers 118 and 104. The method for removing portions of the isolation structures 116 is, for example, wet etching, which is a buffer oxide etch (BOE) process using a mixed solution of HF and NH₄F.

It should be noted that in this embodiment, the insulating material layer that forms the isolation structures 116 and the passivation layer 110 are both made of silicon oxide, so when the wet etching is performed to remove portions of the isolation structures 116, a portion of the passivation layer 110 may also be eroded. However, as the wet etching rate of the isolation structure 116 is greater than that of the passivation layer 110, for example, the wet etching selectivity ratio is 3:1; the passivation layer 110 can protect the tunneling dielectric layer 102 from being eroded by the etchant, so as not to expose the substrate 100. In this embodiment, as shown in FIG. 1D, when portions of the isolation structures 116 are removed, the passivation layer 110 on the surface of the trenches 108 is still remained, so as to prevent the substrate 100 from directly contacting the control gate to be formed subsequently to cause current leakage. In other embodiments, the passivation layer 100 includes an insulating layer 114 made of silicon nitride and a liner 112 made of silicon oxide. As the etching selectivity ratio of silicon nitride to silicon oxide is high, the passivation layer 100 can provide a better protection during the process of etching portions of the isolation structures 116.

Then, referring to FIG. 1D, a conductive layer 120 is formed on the substrate 100, and covered on the conductive layer 118 and the isolation structures 116. The material of the conductive layer 120 is, for example, doped polysilicon. The conductive layer 120 is formed by performing CVD, for example. Next, a portion of the conductive layer 120 located in the trenches 108 is removed, so as to expose a portion of the surface of the isolation structures 116. The method for removing a portion of the conductive layer 120 is, for example, anisotropic etch-back. In this manner, the remaining conductive layer 120 is, for example, distributed in stripes on both sidewalls of the conductive layer 104 and the conductive layer 118.

Next, a patterning process is performed to etch the conductive layers 104, 118, and 120 simultaneously, so as to form a floating gate 122 distributed in blocks on the substrate 100. In this embodiment, the floating gate 122 includes the conductive layer 120 located on the sidewalls of the conductive layers 104 and 118 in addition to the conductive layers 104 and 118, such that the size of the floating gate 122 is increased. As the conductive layer 120 enlarges the surface area of the floating gate 122, the capacitance contact area between the floating gate 122 and the control gate to be formed subsequently is increased, thus enhancing the GCR of the memory.

Referring to FIG. 1E, an inter-gate dielectric layer 124 is formed on the substrate 100. The inter-gate dielectric layer 124 is, for example, conformably covered on the floating gate 122 and the isolation structures 116. The inter-gate dielectric layer 124 is, for example, a composite dielectric layer formed by a stack of silicon oxide/silicon nitride/silicon oxide (ONO) or silicon oxide/silicon nitride (ON), or is made of suitable dielectric materials such as silicon oxide and silicon nitride. The method for forming the above dielectric materials (like silicon oxide, silicon nitride) is, for example, CVD. Afterwards, a control gate 126 is formed on the substrate 100. The method for forming the control gate 126 includes, for example, first forming a conductive material layer (not shown) on the substrate 100, and then performing a patterning process to etch the conductive material layer. The material of the conductive material layer is, for example, doped polysilicon. The conductive material layer is formed by performing CVD, for example. As the control gate 126 is covered on the top surface of the floating gate 122, and meanwhile on the sidewalls of the floating gate 122, the coverage area of the control gate 126 on the floating gate 122 is expanded, thus enhancing the GCR between the control gate 126 and the floating gate 122.

The subsequent steps, such as the steps of forming a source, drain, contact plug, and conducting wire in the method for forming a memory, are known to those skilled in the art, so the details will not be described herein again.

For example, the gate structure of the memory of the present invention is illustrated in FIG. 1E.

Referring to FIG. 1E, the memory of the present invention includes isolation structures 116, a passivation layer 110, a gate structure 130, and a source/drain region (not shown). The isolation structures 116 (for example, trench isolation structures) are disposed in the substrate 100, and the surface of the isolation structures 116 is lower than that of the substrate 100. The passivation layer 110 is disposed between the isolation structures 116 and the substrate 100. The passivation layer 110 is, for example, a composite layer, composed of a silicon oxide liner 112 formed by thermal oxidation and a silicon oxide or silicon nitride insulating layer 114 formed by HDP-CVD, and the etching rate of the isolation structures 116 is greater than that of the passivation layer 110.

In view of the above, the gate structure 130 includes a floating gate 122, a tunneling dielectric layer 102, a control gate 126, and an inter-gate dielectric layer 124. The floating gate 122 is disposed on the substrate 100 between two adjacent isolation structures 116, and is covered on a portion of the top surface of the isolation structures 116. The material of the floating gate 122 is, for example, doped polysilicon. The tunneling dielectric layer 102 is disposed between the floating gate 122 and the substrate 100, and the material thereof is, for example, silicon oxide. The control gate 126 is disposed on the substrate 100, and is covered on the top surface and the sidewall of the floating gate 122 and the isolation structures 116. The material of the control gate 126 is, for example, doped polysilicon. The inter-gate dielectric layer 124 is disposed between the control gate 126 and the floating gate 122, and between the control gate 126 and the substrate 100. The inter-gate dielectric layer 124 is, for example, a composite dielectric layer formed by a stack of silicon oxide/silicon nitride/silicon oxide (ONO). The source/drain region is disposed in the substrate 100 on both sides of the gate structure 130.

It should be noted that in the gate structure 130 of the memory of the present invention, as the surface of the isolation structures 116 is lower than that of the substrate 100, the floating gate 122 is covered on a portion of the surface of the isolation structures 116. As a result, the size of the floating gate 122 is enlarged, and the coverage area of the control gate 126 on the floating gate 122 is increased, thus enhancing the GCR to improve the performance of the memory.

In view of the above, in the method for fabricating a memory provided by the present invention, a passivation layer is formed between the trench isolation structures and the substrate, and then portions of the isolation structures are removed for lowering the surface of the isolation structures than that of the substrate, so as to obtain a larger-sized floating gate. Therefore, the contact area between the floating gate and the control gate is increased to enhance the GCR of the memory, thus lowering the operating voltage of the device and improving the device performance.

Moreover, when portions of the isolation structures are removed, compared with the isolation structures, the passivation layer with a lower etching rate can be prevented from being excessively removed to expose the substrate, thereby avoiding causing the problem of current leakage.

Further, the method of the present invention is carried out by a simple process, and thus the fabrication cost can be effectively reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a memory, comprising:
providing a substrate, wherein a tunneling dielectric layer, a first conductive layer, and a mask layer are formed in sequence on the substrate;
patterning the mask layer, the first conductive layer, the tunneling dielectric layer, and the substrate to form a plurality of trenches in the substrate;
forming a passivation layer on the surface of the trenches;
forming a plurality of isolation structures to fill the trenches, wherein an etching rate of the isolation structures is greater than that of the passivation layer;
removing the mask layer to expose the first conductive layer;
forming a second conductive layer on the first conductive layer;
removing portions of the isolation structures, for lowering the surface of the isolation structures than that of the substrate and exposing sidewalls of the first and the second conductive layers;
forming a third conductive layer on the exposed sidewalls of the first and the second conductive layers;
patterning the third conductive layer, the second conductive layer, and the first conductive layer to form a plurality of floating gates;
forming an inter-gate dielectric layer on the substrate; and
forming a control gate on the substrate.

2. The method for fabricating a memory as claimed in claim 1, wherein the passivation layer comprises a composite layer.

3. The method for fabricating a memory as claimed in claim 2, wherein steps for forming the composite layer comprise:
forming a liner on the surface of the trenches; and
forming an insulating layer on the surface of the trenches.

4. The method for fabricating a memory as claimed in claim 3, wherein a material of the insulating layer comprises silicon oxide formed by high-density plasma chemical vapor deposition (HDP-CVD).

5. The method for fabricating a memory as claimed in claim 3, wherein the material of the insulating layer comprises silicon nitride.

6. The method for fabricating a memory as claimed in claim 3, wherein a process for forming the liner comprises thermal oxidation.

7. The method for fabricating a memory as claimed in claim 1, wherein a process for removing portions of the isolation structures comprises wet etching.

8. The method for fabricating a memory as claimed in claim 1, wherein steps for forming the isolation structures comprise:
forming an insulating material layer on the substrate to fill the trenches; and
removing the portion of the insulating material layer remaining outside the trenches.

9. The method for fabricating a memory as claimed in claim 7, wherein a material of the insulating material layer comprises a spin-on dielectric (SOD) material.

10. The method for fabricating a memory as claimed in claim 1, wherein steps for forming the third conductive layer comprise:
forming a conductive material layer to cover the second conductive layer and the isolation structures; and
removing portions of the conductive material layer to expose the surface of the isolation structures.

11. The method for fabricating a memory as claimed in claim 10, wherein a process for removing portions of the conductive material layer comprises etch-back.

12. A memory, comprising:
a plurality of trench isolation structures, disposed in a substrate, wherein a surface of the trench isolation structures is lower than that of the substrate;
a plurality of passivation layers, disposed between the trench isolation structures and the substrate, wherein an etching rate of the trench isolation structures is greater than that of the passivation layers;
a gate structure, comprising:
a floating gate, disposed on the substrate between two adjacent trench isolation structures, wherein the floating gate is covered on a portion of the surface of the trench isolation structures;
a tunneling dielectric layer, disposed between the floating gate and the substrate;
a control gate, disposed on the substrate and covered on the floating gate and the trench isolation structures; and
an inter-gate dielectric layer, disposed between the control gate and the floating gate, and between the control gate and the substrate; and
a source/drain region, disposed in the substrate at both sides of the gate structure.

13. The memory as claimed in claim 12, wherein the passivation layer comprises a composite layer.

14. The memory as claimed in claim 13, wherein the composite layer comprises a silicon oxide layer.

15. The memory as claimed in claim 13, wherein the composite layer comprises a silicon nitride layer.

16. The memory as claimed in claim 12, wherein a material of the trench isolation structures comprises spin-on dielectric (SOD) material.

17. The memory as claimed in claim 12, wherein a material of the floating gate comprises doped polysilicon.

18. The memory as claimed in claim 12, wherein a material of the control gate comprises doped polysilicon.

19. The memory as claimed in claim 12, wherein a material of the tunneling dielectric layer comprises silicon oxide.

20. The memory as claimed in claim 12, wherein a material of the inter-gate dielectric layer comprises silicon oxide/silicon nitride/silicon oxide (ONO).
